(19) United States
(12) Patent Application Publication
(10) Pub. No.: US 2026/0250608 A1
(43) Pub. Date: Aug. 27, 2026

(54) THINNER COMPOSITION

(71) Applicant: DONGWOO FINE-CHEM CO., LTD., Iksan-si (KR)

(72) Inventors: Somin LEE, Iksan-si (KR); Ji Min CHUN, Iksan-si (KR); Jong Hwan KIM, Iksan-si (KR)

(73) Assignee: DONGWOO FINE-CHEM CO., LTD., Iksan-si (KR)

(21) Appl. No.: 19/537,790

(22) Filed: Feb. 12, 2026

(30) Foreign Application Priority Data
Feb. 27, 2025 (KR) 10-2025-0025982

(51) Int. Cl. C11D 7/50; C11D 7/26; G03F 7/16; H10P 76/00

(52) U.S. Cl. CPC C11D 7/5022; C11D 7/263; G03F 7/168; H10P 76/00

(57) ABSTRACT

The present invention provides a thinner composition comprising a lactone-based organic solvent, an aliphatic ether compound having a specific structure, and one or more of a ketone-based organic solvent or an ester-based organic solvent. The thinner composition according to the present invention has improved EBR and RRC properties due to excellent solubility for photoresist films and spin-on hardmasks (SOHs). The thinner composition according to the present invention can reduce hump heights and improve coating film uniformity.

### CROSS REFERENCE TO RELATED APPLICATIONS

This application claims priority based on Korean Patent Application No. 10-2025-0025982, filed Feb. 27, 2025, the entire content of which is incorporated herein by reference in its entirety.

### TECHNICAL FIELD

The present invention relates to a thinner composition. More particularly, the present invention relates to a thinner composition with improved EBR and RRC properties due to excellent solubility for various photoresist films and spin-on hardmasks (SOHs), which can reduce hump heights and improve coating film uniformity.

### BACKGROUND ART

In the manufacturing process of semiconductor devices, the process of applying a resist on a wafer, transferring a designed pattern, and then etching it to create a fine circuit pattern such as a semiconductor integrated circuit is called the photolithography process. This is accomplished by applying, exposing, developing, etching, and peeling to realize the desired fine circuit pattern.

During the photolithography process, after the resist is uniformly applied on the surface of the wafer, it is necessary to remove the excess photoresist on the edge or backside of the wafer. This is because the presence of resist on the edge or backside of the wafer can cause various defects in subsequent processes such as etching, ion implantation, etc., resulting in a decrease in the yield of the entire semiconductor device.

In order to remove the resist present on the edge or backside of the wafer, a method of installing spray nozzles on the top and bottom of the edge portion of the wafer and spraying a thinner composition containing an organic solvent through the nozzles on the edge or backside of the wafer has been conventionally used.

For example, Korean Patent Publication No. 10-2013-0125029A discloses a thinner composition that can be used for such wafer processing, comprising: a) methoxypropanolacetic acid, b) methyl 2-hydroxyisobutyrate, and c) 1-methoxy-2-propanol.

Currently, photoresists such as i-line photoresists, KrF photoresists, ArF photoresists, EUV photoresists, and spin-on hardmasks (SOH) used in semiconductor lithography processes have different main components. Therefore, it is necessary to adjust the composition content of organic solvents to improve the solubility and applicability of all of them.

On the other hand, thinner compositions include high polarity components to improve solubility and edge bead removal (EBR) properties for high polarity photoresists. If the polarity is too high, it may accelerate the swelling of the photoresist from the EBR end toward the center of the wafer, resulting in a higher hump height. The high hump height reduces the usable area and increases the defects caused by the hump in the subsequent process, which reduces the yield.

Therefore, there is a need to develop a thinner composition having excellent solubility for various photoresist films and spin-on hardmasks (SOHs) to improve EBR and RRC properties and capable of reducing the hump height and improving the uniformity of the coating film.

### DISCLOSURE

### Technical Problem

An object of the present invention is to provide a thinner composition with improved EBR and RRC properties due to excellent solubility for various photoresist films and spin-on hardmasks (SOHs), which can reduce hump heights and improve coating film uniformity.

### Technical Solution

An aspect of the present invention relates to a thinner composition comprising:
a lactone-based organic solvent;
a compound of the following formula (1); and
one or more of a ketone-based organic solvent or an ester-based organic solvent:

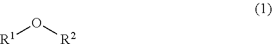

wherein,
R¹ and R² are each independently a C₂-C₈ hydrocarbon.

In one embodiment of the present invention, the lactone-based organic solvent may be one or more selected from the group consisting of γ-butyrolactone, γ-valerolactone, δ-valerolactone, and ε-caprolactone.

In one embodiment of the present invention, R¹ and R² may each independently be a C₂-C₈ alkyl.

In one embodiment of the present invention, the compound of the above formula (1) may be one or more selected from the group consisting of diethyl ether, dipentyl ether, di-n-octyl ether, and ethylpropyl ether.

In one embodiment of the present invention, the ketone-based organic solvent may be one or more selected from the group consisting of methyl ethyl ketone, cyclopentanone, and cyclohexanone.

In one embodiment of the present invention, the ester-based organic solvent may be one or more selected from the group consisting of ethyl 3-ethoxypropionate, methyl 3-methoxypropionate, n-butyl acetate, methyl 2-hydroxyisobutyrate, and ethyl lactate.

The thinner composition according to one embodiment of the present invention may comprise 0.5 to 20 wt % of the lactone-based organic solvent; 0.0005 to 0.2 wt % of the compound of the above formula (1); and 79.8 to 99.3 wt % of one or more of the ketone-based organic solvent or the ester-based organic solvent.

The thinner composition according to one embodiment of the present invention may comprise 1 to 10 wt % of the lactone-based organic solvent; 0.001 to 0.1 wt % of the compound of the above formula (1); and 89.9 to 98.9 wt % of one or more of the ketone-based organic solvent or the ester-based organic solvent.

The thinner composition according to one embodiment of the present invention may comprise 0.5 to 20 wt % of the lactone-based organic solvent; 0.0005 to 0.2 wt % of the compound of the above formula (1); 30 to 60 wt % of the ketone-based organic solvent; and 35 to 65 wt % of the ester-based organic solvent.

The thinner composition according to one embodiment of the present invention may not comprise a glycol ether-based organic solvent.

The thinner composition according to one embodiment of the present invention may be for one or more of a photoresist film or a spin-on hardmask (SOH).

In one embodiment of the present invention, the photoresist film may be a photoresist film for ArF, KrF, or EUV.

According to another aspect, the present invention provides a method of treating a substrate comprising:
modifying the substrate with the thinner composition of the present invention, and
applying a photoresist or spin-on hard mask (SOH) on the modified substrate.

The method according to one embodiment of the present invention may further treat the substrate with the thinner composition after applying the photoresist or spin-on hard mask (SOH) on the modified substrate.

According to yet another aspect, the present invention provides a method of treating a substrate comprising:
applying a photoresist or spin-on hard mask (SOH) on the substrate to form a film, and
treating the film with the thinner composition.

### Advantageous Effects

The thinner composition according to the present invention has excellent solubility for photoresist films and spin-on hardmasks (SOHs), resulting in improved EBR and RRC properties. The thinner composition according to the present invention can reduce the hump height and improve the uniformity of the coating film.

### BEST MODE

Hereinafter, the present invention will be described in more detail.

One embodiment of the present invention relates to a thinner composition comprising a lactone-based organic solvent (A); an aliphatic ether compound (B) having a specific structure; and one or more of a ketone-based organic solvent or an ester-based organic solvent (C).

The thinner composition according to the present invention can be effectively used to reduce the amount of photoresist film and/or spin-on hardmask (SOH) used in semiconductor device and display manufacturing processes or eliminate them.

The thinner composition according to the present invention has its polarity adjusted such that when the photoresist applied onto the wafer during the EBR process is rapidly wiped away by the thinner, the rate at which the photoresist at the edge portion swells inward due to the thinner is selectively controlled, thereby reducing the hump height. Accordingly, the yield can be improved by increasing the usable area and reducing the defects caused by the hump in subsequent processes.

Further, the thinner composition according to the present invention can reduce the amount of photoresist and/or spin-on hardmask used in the process by increasing the reactivity of the composition forming the photoresist film and/or spin-on hardmask with the substrate surface, allowing a smaller amount to be dispersed more extensively on the substrate.

Furthermore, the thinner composition according to the present invention can improve the uniformity of the coating film.

Accordingly, the thinner composition according to the present invention is suitable for use in the process of forming photoresist films and/or spin-on hardmasks (SOHs) for purposes such as edge bead removal (EBR), back rinse, and resist reduced coating (RRC). For example, the photoresist film may be a photoresist film for ArF, KrF, or EUV.

### Lactone-Based Organic Solvent (A)

In one embodiment of the present invention, the lactone-based organic solvent (A) possesses relatively high viscosity characteristics and a high boiling point, thereby suppressing its penetration characteristics into the photoresist. Accordingly, the lactone-based organic solvent (A) exhibits EBR images with high straightness and plays a role in enhancing RRC characteristics by controlling the PR spreading performance in the thinner of the mixed composition.

The lactone-based organic solvent has a structure containing an ester functional group within a hydrocarbon ring and is generally a highly polar substance. The lactone-based organic solvent may have lactone structures such as tricyclic, tetracylic, pentacyclic, hexacyclic, and heptacyclic, depending on the number of carbon atoms forming the ring; however, lactone compounds with five or more carbon atoms, which have stable bond angles, are preferred. For example, the lactone-based organic solvent includes γ-butyrolactone, γ-valerolactone, δ-valerolactone, and ε-caprolactone, which can be used alone or in combinations of two or more.

In one embodiment of the present invention, the lactone-based organic solvent may be included in an amount of 0.5 to 20 wt %, preferably 1 to 10 wt %, based on the total 100 wt % of the thinner composition. When the lactone-based organic solvent is used within the above content range, it can exhibit improved EBR and RRC performance. If the lactone-based organic solvent is included in an amount below the above content range, EBR performance is significantly degraded, and depending on the process conditions, tearing may occur during photoresist coating. Furthermore, if included in an amount exceeding the above content range, it may exhibit residue problems due to poor volatilization. Consequently, after the EBR process, the image may appear unclean with a wavy pattern and show a tendency to be blurred. Additionally, due to the uncleanly wiped EBR, the hump height may exhibit a tendency to flow.

### Ether Compound (B)

In one embodiment of the present invention, the ether compound (B) acts as a factor that can control the phenomenon where the photoresist swells and curls inward from the EBR end toward the center of the wafer by adjusting the high polarity difference between the solvents included in the thinner composition and regulating solubility.

Specifically, the ether compound (B), when used with the lactone-based organic solvent, prevents excessive tearing of the photoresist after RRC in the process and prevents excessive thinning of the edges during photoresist coating due to the thinner, thereby enabling improved uniformity.

Specifically, the ether compound is a compound of the following formula (1).

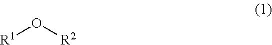

wherein,
R¹ and R² are each independently a C₂-C₈ hydrocarbon.

The term “C₂-C₈ hydrocarbon” as used herein means a straight-chain or branched, saturated or unsaturated hydrocarbon having 2 to 8 carbon atoms, and examples includes a C₂-C₈ alkyl, a C₂-C₈ alkenyl, or a C₂-C₈ alkynyl.

The term “C₂-C₈ alkyl” as used herein means a straight-chain or branched, monovalent saturated hydrocarbon having 2 to 8 carbon atoms, and examples includes, but are not limited to, ethyl, n-propyl, i-propyl, n-butyl, i-butyl, t-butyl, n-pentyl, n-hexyl, and the like.

The term “C₂-C₈ alkenyl” as used herein means a straight-chain or branched unsaturated hydrocarbon having 2 to 8 carbon atoms with one or more carbon-carbon double bonds, and examples includes, but are not limited to, ethylenyl, propenyl, butenyl, pentenyl, and the like.

The term “C₂-C₈ alkynyl” as used herein means a straight-chain or branched unsaturated hydrocarbon having 2 to 8 carbon atoms with one or more carbon-carbon triple bonds, and examples includes, but are not limited to, acetylenyl, propynyl, butynyl, and the like.

In one embodiment of the present invention, controlling the carbon number of R¹ and R² to 2 to 8 enables a low hump height, thereby increasing the usable area after PR coating.

When the number of carbons in the chain exceeds 8, low volatility performance may cause unevenness in the PR coating. Consequently, the photoresist may exhibit tearing after coating. Furthermore, when the number of carbons in the chain is less than 2, poor volatility may cause photoresist residue issues. Therefore, it is desirable to formulate the composition to have an appropriate carbon number.

Specifically, to improve EBR and RRC characteristics, lower the hump height, and enhance coating film uniformity, R¹ and R² may each independently be a C₂-C₈ alkyl.

Examples of the compound of the above formula (1) include diethyl ether, dipentyl ether, di-n-octyl ether, ethylpropyl ether, and the like. These may be used alone or in combinations of two or more.

In one embodiment of the present invention, the ether compound may be included in an amount of 0.0005 to 0.2 wt %, preferably 0.001 to 0.1 wt %, based on 100 wt % of the total composition. If the ether compound is included in an amount below the above content range, the EBR characteristics may deteriorate due to reduced dissolution performance. Furthermore, if included in an amount exceeding the above content range, excessive dissolution may cause PR tailing, where the photoresist at the EBR end appears blurred, and the EBR may lose its straightness.

### One or More of a Ketone-Based Organic Solvent or an Ester-Based Organic Solvent (C)

In one embodiment of the present invention, one or more of a ketone-based organic solvent or an ester-based organic solvent (C) serve to improve the EBR image and reduce the hump height by adjusting the polarity of the composition while providing an appropriate dissolution rate for various types of photoresists.

The ketone-based organic solvent has fast volatilization characteristics, reducing sagging during drying in the EBR process. However, as the content of the ketone-based organic solvent increases, resist tearing may occur after RRC.

Examples of the ketone-based organic solvent include cyclic ketone-based organic solvents and acyclic ketone-based organic solvents.

The cyclic ketone-based organic solvent exhibits high affinity for resists containing similar cyclic resins and, due to its high polarity, demonstrates high solubility for most photoresists.

In contrast, the relatively low-polarity acyclic ketone-based organic solvent significantly slows the EBR speed, potentially causing a residue phenomenon where resin appears to remain at the edges.

Therefore, it is preferable to use cyclic ketone-based organic solvents as the ketone-based organic solvent.

Examples of the ketone-based organic solvent include methyl ethyl ketone, cyclopentanone, cyclohexanone, and the like. These can be used alone or in combinations of two or more.

The ester-based organic solvent is a solvent with relatively lower polarity than a ketone-based organic solvent or a lactone-based organic solvent. When mixed with compounds exhibiting higher polarity than these, it can selectively control solvents that tend to remain longer on the silicon substrate surface, thereby improving resist tearing after RRC.

However, increasing the ester-based organic solvent content reduces the tendency of the lactone-based organic solvent and ether compound to remain on the wafer surface, potentially degrading uniformity after photoresist coating. This phenomenon occurs because the amount remaining on the wafer surface becomes relatively small, and it appears alongside the resist tearing characteristics after RRC. Therefore, it is necessary to use an appropriate amount of ester-based organic solvent.

Examples of the ester-based organic solvent include ethyl 3-ethoxypropionate, methyl 3-methoxypropionate, n-butyl acetate, methyl 2-hydroxyisobutyrate, ethyl lactate, and the like. These may be used alone or in combinations of two or more.

The ketone-based organic solvent and ester-based organic solvent may be used alone or in combinations of two or more without adversely affecting RRC performance. However, using them in combination rather than alone is preferable as it enhances the solubility of photoresists with diverse compositions, thereby improving EBR, hump height, RRC, and uniformity performance.

In one embodiment of the present invention, one or more of the ketone-based organic solvent or the ester-based organic solvent may be included in an amount of 79.8 to 99.3 wt %, preferably 89.9 to 98.9 wt %, based on 100 wt % of the entire thinner composition. When one or more of the ketone-based organic solvent or the ester-based organic solvent are used within the above content range, improved RRC performance can be exhibited. If the content of one or more of the ketone-based organic solvent or ester-based organic solvent does not satisfy the above range, for example, if it is below the content range, a decrease in dissolution speed may cause a deterioration in EBR and hump height performance, and the volatilization speed may also become very poor, resulting in poor RRC performance.

Furthermore, if either the ketone-based organic solvent or the ester-based organic solvent is used in excessively large quantities, the other solvent cannot exhibit its performance and instead follows the characteristics of the excessively used solvent. Consequently, it cannot provide appropriate EBR and RRC performance for various photoresists. Therefore, to ensure that the characteristics of the individual solvents do not dominate but rather that their combined use allows only their advantages to be realized, it is desirable to use the ketone-based organic solvent within a content range of 30 to 60 wt % and the ester-based organic solvent within a content range of 35 to 65 wt %.

Glycol ether-based organic solvents are commonly used as organic solvents in thinner compositions. Glycol ether-based organic solvents exhibit excellent reactivity with the hydroxyl groups present in the resin, enabling rapid dissolution rates. However, when glycol ether-based organic solvents are present in excess, dissolution occurs too rapidly in thin film photoresists, leading to tearing characteristics. It also results in the EBR not forming straight lines, instead exhibiting a pattern where the ends appear to burst.

Therefore, the thinner composition according to one embodiment of the present invention may preferably not contain a glycol ether-based organic solvent.

Examples of the glycol ether-based organic solvent include ethylene glycol monomethyl ether, ethylene glycol monoethyl ether, ethylene glycol monoisopropyl ether, ethylene glycol monobutyl ether, diethylene glycol monomethyl ether, diethylene glycol monoethyl ether, diethylene glycol monoisopropyl ether, diethylene glycol monobutyl ether, triethylene glycol monomethyl ether, triethylene glycol monoethyl ether, triethylene glycol monoisopropyl ether, triethylene glycol monobutyl ether, polyethylene glycol monomethyl ether, polyethylene glycol monobutyl ether, propylene glycol monomethyl ether, dipropylene glycol monomethyl ether, tripropylene glycol monomethyl ether, propylene glycol monomethyl ether acetate, and the like.

Meanwhile, aqueous quaternary ammonium hydroxide solution, one of the basic solvents used in NTD pattern trimming compositions, can selectively remove photoresist after exposure. However, it is highly toxic and, due to its high water solubility, exhibits excellent hygroscopicity, which can cause toxicity within the body.

Therefore, the thinner composition according to one embodiment of the present invention may preferably not contain aqueous quaternary ammonium hydroxide.

Furthermore, alkaline solvents do not volatilize from the wafer surface after use but remain, potentially causing foaming during subsequent processes. This can lead to equipment contamination or corrosion of process line materials. Accordingly, it is preferable that the thinner composition according to one embodiment of the present invention does not contain organic alkali and/or inorganic alkali.

Furthermore, during the process, the thinner solution is applied under strong spin conditions, and foam may form on the wafer surface due to splashing. This can lead to wafer contamination. Because there is a risk of equipment contamination, it is preferable that the thinner composition according to one embodiment of the present invention does not contain surfactants, such as nonionic fluorinated surfactants.

The thinner composition according to one embodiment of the present invention may comprise 0.5 to 20 wt % of a lactone-based organic solvent; 0.0005 to 0.2 wt % of a compound of the above formula (1); and 79.8 to 99.3 wt % of one or more of a ketone-based organic solvent or an ester-based organic solvent.

The thinner composition according to one embodiment of the present invention may comprise 1 to 10 wt % of a lactone-based organic solvent; 0.001 to 0.1 wt % of a compound of the above formula (1); and 89.9 to 98.9 wt % of one or more of a ketone-based organic solvent or an ester-based organic solvent.

The thinner composition according to one embodiment of the present invention may comprise 0.5 to 20 wt % of a lactone-based organic solvent; 0.0005 to 0.2 wt % of a compound of the above formula (1); 30 to 60 wt % of a ketone-based organic solvent; and 35 to 65 wt % of an ester-based organic solvent.

The thinner composition according to one embodiment of the present invention may comprise 1 to 10 wt % of a lactone-based organic solvent; 0.001 to 0.1 wt % of a compound of the above formula (1); 30 to 60 wt % of a ketone-based organic solvent; and 35 to 65 wt % of an ester-based organic solvent.

One embodiment of the present invention relates to a method of treating a substrate using the thinner composition described above.

A method of treating a substrate according to one embodiment of the present invention may comprise the steps of modifying the substrate with the thinner composition, and applying a photoresist or SOH on the modified substrate.

By performing the substrate modification step prior to applying the photoresist or SOH, the removal process can be performed effectively without causing tailing phenomenon in the edge bead removing (EBR) process, excellent coating uniformity can be maintained, and the reducing resist consumption (RRC) effect, which enables coating a wafer with a small amount of photoresist or SOH, can be maximized.

The modification step may be performed by applying the thinner composition according to the present invention in a conventional manner. For example, the modification step may be performed by spraying the thinner composition onto the center of a stationary substrate and then rotating the substrate so that the sprayed thinner composition is spread over the entire surface of the substrate. The amount of spraying may be from 0.1 cc to 5 cc.

The photoresist used in the application step may be at least one of photoresists for ArF, KrF or EUV. Further, the SOH used in the application step may be at least one of C—SOH or Si—SOH. When C—SOH is used, stability at high temperature is excellent, and when Si—SOH is used, optical properties are easily controllable.

The method of treating the substrate may further comprise, after the step of applying the photoresist or SOH, the step of treating the substrate with the thinner composition according to the present invention.

By treating the substrate with the thinner composition after the application step of the photoresist or SOH, excess photoresist film or SOH applied on the edge or backside of the substrate can be quickly and effectively removed prior to the exposure process.

A method of treating a substrate according to one embodiment of the present invention may comprise the steps of applying a photoresist or SOH on a substrate to form a film, and treating the film with the thinner composition according to the present invention.

By treating the substrate with the thinner composition after the application step of the photoresist or SOH, excess photoresist film or SOH applied on the edge or backside of the substrate can be quickly and effectively removed prior to the exposure process.

The method of treating the substrate may comprise the steps of treating the SOH-coated substrate with the thinner composition, then applying a photoresist, and then treating the substrate again with the thinner composition.

By applying the photoresist and subsequently treating the substrate again with the thinner composition in the above steps, excess photoresist and SOH applied on the edge or backside of the substrate can be quickly and effectively removed prior to the exposure process.

Hereinafter, the present invention will be described more specifically by means of Examples, Comparative Examples, and Experimental Examples. These Examples, Comparative Examples, and Experimental Examples are intended to illustrate the present invention only, and it is obvious to those skilled in the art that the scope of the present invention is not limited to them.

### Examples and Comparative Examples: Preparation of Thinner Compositions

Thinner compositions were prepared by mixing the components in the composition of Table 1 (unit: parts by weight) below.

TABLE 1

| | (A) Lactone-based | | | | | | | | | | | | | | |
|---|---|---|---|---|---|---|---|---|---|---|---|---|---|---|---|
| | organic solvent | | | (B) Ether compound | | | | (C) Organic solvent | | | | | | | |
| | A-1 | A-2 | A-3 | B-1 | B-2 | B-3 | B-4 | C-1 | C-2 | C-3 | C-4 | C-5 | C-6 | C-7 | C-8 |
| Example 1 | 5 | | | | 0.008 | | | 95 | | | | | | | |
| Example 2 | 5 | | | | 0.008 | | | | 95 | | | | | | |
| Example 3 | 5 | | | | 0.008 | | | | | 95 | | | | | |
| Example 4 | 5 | | | | 0.008 | | | | | | | 95 | | | |
| Example 5 | 5 | | | | 0.008 | | | | | | | | 95 | | |
| Example 6 | 5 | | | 0.008 | | | | | | 95 | | | | | |
| Example 7 | 5 | | | | | 0.008 | | | | 95 | | | | | |
| Example 8 | | 5 | | | 0.008 | | | | | 95 | | | | | |
| Example 9 | | | 5 | | 0.008 | | | | | 95 | | | | | |
| Example 10 | 0.1 | | | | 0.008 | | | | 50 | 50 | | | | | |
| Example 11 | 0.5 | | | | 0.008 | | | | 49 | 50 | | | | | |
| Example 12 | 1 | | | | 0.008 | | | | 49 | 50 | | | | | |
| Example 13 | 5 | | | | 0.008 | | | | 45 | 50 | | | | | |
| Example 14 | 10 | | | | 0.008 | | | | 40 | 50 | | | | | |
| Example 15 | 20 | | | | 0.008 | | | | 30 | 50 | | | | | |
| Example 16 | 25 | | | | 0.008 | | | | 25 | 50 | | | | | |
| Example 17 | 5 | | | | 0.0001 | | | | 45 | 50 | | | | | |
| Example 18 | 5 | | | | 0.0005 | | | | 45 | 50 | | | | | |
| Example 19 | 5 | | | | 0.001 | | | | 45 | 50 | | | | | |
| Example 20 | 5 | | | | 0.01 | | | | 45 | 50 | | | | | |
| Example 21 | 5 | | | | 0.1 | | | | 45 | 50 | | | | | |
| Example 22 | 5 | | | | 0.2 | | | | 45 | 50 | | | | | |
| Example 23 | 5 | | | | 0.3 | | | | 45 | 50 | | | | | |
| Example 24 | 5 | | | | 0.008 | | | | 30 | 65 | | | | | |
| Example 25 | 5 | | | | 0.008 | | | | 30 | | 65 | | | | |
| Example 26 | 5 | | | | 0.008 | | | | 30 | | | 65 | | | |
| Example 27 | 5 | | | | 0.008 | | | | 30 | | | | 65 | | |
| Example 28 | 5 | | | | 0.008 | | | | 60 | 35 | | | | | |
| Example 29 | 5 | | | | 0.008 | | | 30 | | 65 | | | | | |
| Example 30 | 5 | | | | 0.008 | | | 30 | | | 65 | | | | |
| Example 31 | 5 | | | | 0.008 | | | 30 | | | | 65 | | | |
| Example 32 | 5 | | | | 0.008 | | | 30 | | | | | 65 | | |
| Comparative | 100 | | | | | | | | | | | | | | |
| Example | | | | | | | | | | | | | | | |
| 1 | | | | | | | | | | | | | | | |
| Comparative | | | | | 100 | | | | | | | | | | |
| Example | | | | | | | | | | | | | | | |
| 2 | | | | | | | | | | | | | | | |
| Comparative | | | | | | | | | | 100 | | | | | |
| Example | | | | | | | | | | | | | | | |
| 3 | | | | | | | | | | | | | | | |
| Comparative | 90 | | | | 10 | | | | | | | | | | |
| Example | | | | | | | | | | | | | | | |
| 4 | | | | | | | | | | | | | | | |
| Comparative | 10 | | | | | | 0.008 | | 40 | 50 | | | | | |
| Example | | | | | | | | | | | | | | | |
| 5 | | | | | | | | | | | | | | | |
| Comparative | | | | | 0.008 | | | | 40 | | 60 | | | | |
| Example | | | | | | | | | | | | | | | |
| 6 | | | | | | | | | | | | | | | |
| Comparative | 5 | | | | | | | | 45 | 50 | | | | | |
| Example | | | | | | | | | | | | | | | |
| 7 | | | | | | | | | | | | | | | |
| Comparative | | | | | 0.008 | | | | | 40 | 60 | | | | |
| Example | | | | | | | | | | | | | | | |
| 8 | | | | | | | | | | | | | | | |
| Comparative | 10 | | | | 0.008 | | | | | | | | | 30 | 60 |
| Example | | | | | | | | | | | | | | | |
| 9 | | | | | | | | | | | | | | | |
| Comparative | 10 | | | | 0.008 | | | | | | | | | 90 | |
| Example | | | | | | | | | | | | | | | |
| 10 | | | | | | | | | | | | | | | |
| Comparative | 10 | | | | 0.008 | | | | | | | | | | 90 |
| Example | | | | | | | | | | | | | | | |
| 11 | | | | | | | | | | | | | | | |

(A) Lactone-based organic solvent
A-1: γ- butyrolactone 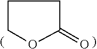
A-2: δ- valerolactone 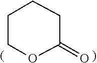
A-3: γ- valerolactone 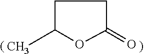
(B) Ether compound
B-1: Diethyl ether
B-2: Dipentyl ether
B-3: Di-n-octyl ether
B-4: Didecyl ether
(C) Organic Solvent
C-1: Methyl ethyl ketone
C-2: Cyclopentanone
C-3: Ethyl 3-ethoxypropionate
C-4: Methyl 3-methoxypropionate
C-5: n-Butyl acetate
C-6: Methyl 2-hydroxyisobutyrate
C-7: Propylene glycol monomethyl ether
C-8: Propylene glycol monomethyl ether acetate

### Experimental Example 1

The thinner compositions prepared in the above Examples and Comparative Examples were evaluated using the photoresist and SOH listed in Table 2 below, under the conditions specified in Table 3 below.

The results are shown in Tables 4 through 5 below.

TABLE 2

| Category | PR type |
|---|---|
| PR 1 | NTD PR A for EUV |
| PR 2 | PTD PR B for EUV |
| PR 3 | PR C for ArF |
| SOH | Universal SOH |

TABLE 3

| Performance | | | Rotational | |
|---|---|---|---|---|
| evaluation | | Time | speed | |
| step | | (seconds) | (rpm) | Description |
| 1 | Thinner | 3 | 0 | 3.5 cc of thinner |
| | application | | | |
| 2 | Dispense | 0.1 | 1000 | |
| | conditions | | | |
| 3 | PR and SOH | 2 | 500 | 0.5 cc to 4 cc of PR and |
| | spray | | | SOH |
| | conditions | | | |
| 4 | PR and SOH | 35 | 500~2000 | Adjust according to the film |
| | coating | | | thickness depending on the |
| | | | | purpose of each type of PR |
| 5 | EBR | 9 | 2000 | and SOH |
| | conditions | | | Thinner spraying speed |
| | | | | 15 mL/min |
| 6 | Soft baking | 50~60 | — | Temperature 90 to 130° C. |
| | | | | depending on PR and SOH |

### (1) RRC (Reducing Resist Coating) Performance Evaluation

Before applying each photoresist onto a 12-inch silicon wafer, 3.5 cc of each thinner composition was applied in a stationary state for 3 seconds. The substrate was then rapidly rotated at 1000 rpm for 0.1 seconds to fully disperse the thinner composition across the upper surface of the wafer. Subsequently, 0.6 cc and 0.8 cc of the three types of photoresists and SOH shown in Table 2 were applied, respectively, and an RRC process evaluation was conducted to measure the application distribution and consumption of photoresists and SOH according to the thinner composition.

The evaluated substrates were measured using a film thickness gauge (VM). Points were evenly sampled across the entire surface to measure film thickness, and uniformity was determined by checking the deviation.

RRC performance and uniformity were evaluated according to the evaluation criteria below.

### <RRC Evaluation Criteria>

⊚: PR is applied to 95% or more of the wafer surface in the RRC result, and there are no spots
∘: PR is applied to 95% or more of the wafer surface in the RRC result, but spots are present
Δ: PR is applied to 80% or more but less than 95% of the wafer surface in the RRC result
x: PR is applied to less than 80% of the wafer surface in the RRC result

### <Uniformity Evaluation Criteria>

⊚: Deviation between the center and edge of the wafer as a result of 0.6 cc PR coating is 10 nm or less
∘: Deviation between the center and edge of the wafer as a result of 0.6 cc PR coating is more than 10 nm and less than or equal to 15 nm
Δ: Deviation between the center and edge of the wafer as a result of 0.6 cc PR coating is more than 15 nm and less than or equal to 20 nm
x: Deviation between the center and edge of the wafer as a result of 0.6 cc PR coating is more than 20 nm

### (2) EBR (Edge Bead Removal) Performance Evaluation

A 12-inch silicon wafer substrate was coated with the photoresist or SOH listed in Table 2 on the entire surface under the evaluation conditions in Table 3 above. Subsequently, EBR performance evaluation was conducted using each thinner composition to remove unwanted PR from the edge regions. This was performed for each photoresist type, and the thinner compositions of the Examples and Comparative Examples were supplied at a constant pressure from a pressurized tank equipped with a pressure gauge. The thinner composition sprayed at a constant pressure was evaluated under conditions where a total of 15 mL/min was sprayed during the EBR process.

The evaluated substrates were examined under an optical microscope (OM) at 100× and 1000× magnifications to check the straightness, uniformity, and tailing of the EBR line to evaluate the EBR according to the following evaluation criteria.

In addition, for the evaluation sample that shows the straightness and uniformity of the EBR line, the film thicknesses at 35 μm inward and 35 μm outward from the EBR line of the photoresist film were measured using a film thickness gauge (Dektak xt, Bruker) to derive the maximum film thickness value. Then, the average thickness of the photoresist film was excluded to calculate the hump height, which was evaluated according to the following evaluation criteria.

### <EBR Evaluation Criteria>

⊚: Straight and uniform EBR line on the photoresist film after EBR
∘: Straight but not uniform EBR line on the photoresist film after EBR
Δ: No straightness and uniformity of EBR line on the photoresist film after EBR
X: EBR line on the photoresist film is not uniform and tailing phenomenon occurs after EBR

### <Hump Height Evaluation Criteria>

⊚: Hump height is 100 Å or less
∘: Hump height exceeds 100 Å but is 500 Å or less
Δ: Hump height exceeds 500 Å but is 1000 Å or less
x: Hump height exceeds 1000 Å

TABLE 4

| | PR 1 | | | | PR 2 | | | |
|---|---|---|---|---|---|---|---|---|
| | | Hump | | | | Hump | | |
| | EBR | height | RRC | Uniformity | EBR | height | RRC | Uniformity |
| Example 1 | Δ | ◯ | ◯ | ◯ | Δ | ◯ | ◯ | ◯ |
| Example 2 | ◯ | ◯ | ◯ | ◯ | ⊚ | ◯ | ◯ | ◯ |
| Example 3 | ◯ | ⊚ | ◯ | ◯ | ◯ | ⊚ | ◯ | ◯ |
| Example 4 | ◯ | ◯ | ◯ | ◯ | ⊚ | ◯ | ◯ | ◯ |
| Example 5 | ⊚ | ◯ | ◯ | ◯ | ⊚ | ⊚ | ◯ | ◯ |
| Example 6 | ◯ | ⊚ | ◯ | ◯ | ◯ | ⊚ | ◯ | ◯ |
| Example 7 | ◯ | ⊚ | ◯ | ◯ | ◯ | ⊚ | ◯ | ◯ |
| Example 8 | ◯ | ⊚ | ◯ | ◯ | ◯ | ⊚ | ◯ | ◯ |
| Example 9 | ◯ | ⊚ | ◯ | ◯ | ◯ | ⊚ | ◯ | ◯ |
| Example 10 | Δ | ◯ | Δ | Δ | Δ | ◯ | ◯ | Δ |
| Example 11 | ◯ | ◯ | ◯ | Δ | ◯ | ◯ | ◯ | Δ |
| Example 12 | ⊚ | ⊚ | ⊚ | ⊚ | ⊚ | ⊚ | ⊚ | ⊚ |
| Example 13 | ⊚ | ⊚ | ⊚ | ⊚ | ⊚ | ⊚ | ⊚ | ⊚ |
| Example 14 | ⊚ | ⊚ | ⊚ | ⊚ | ⊚ | ⊚ | ⊚ | ⊚ |
| Example 15 | ◯ | ◯ | ◯ | ◯ | ◯ | ◯ | ◯ | ◯ |
| Example 16 | Δ | Δ | Δ | ◯ | Δ | Δ | Δ | ◯ |
| Example 17 | Δ | ◯ | ◯ | ◯ | Δ | ◯ | ◯ | ◯ |
| Example 18 | ◯ | ◯ | ⊚ | ⊚ | ◯ | ◯ | ⊚ | ⊚ |
| Example 19 | ⊚ | ⊚ | ⊚ | ⊚ | ⊚ | ⊚ | ◯ | ⊚ |
| Example 20 | ⊚ | ⊚ | ⊚ | ⊚ | ⊚ | ◯ | ⊚ | ⊚ |
| Example 21 | ⊚ | ⊚ | ⊚ | ⊚ | ⊚ | ⊚ | ⊚ | ⊚ |
| Example 22 | ◯ | ◯ | ⊚ | ⊚ | ◯ | ◯ | ◯ | ⊚ |
| Example 23 | Δ | ◯ | ◯ | ◯ | Δ | ◯ | ◯ | ◯ |
| Example 24 | ⊚ | ⊚ | ⊚ | ⊚ | ⊚ | ⊚ | ⊚ | ⊚ |
| Example 25 | ⊚ | ⊚ | ⊚ | ⊚ | ⊚ | ⊚ | ⊚ | ⊚ |
| Example 26 | ⊚ | ⊚ | ⊚ | ⊚ | ⊚ | ⊚ | ⊚ | ⊚ |
| Example 27 | ⊚ | ⊚ | ⊚ | ⊚ | ⊚ | ⊚ | ⊚ | ⊚ |
| Example 28 | ⊚ | ⊚ | ⊚ | ⊚ | ⊚ | ⊚ | ⊚ | ⊚ |
| Example 29 | ◯ | ◯ | ⊚ | ◯ | ◯ | ◯ | ⊚ | ◯ |
| Example 30 | ◯ | ◯ | ⊚ | ⊚ | ◯ | ◯ | ⊚ | ◯ |
| Example 31 | ◯ | ◯ | ⊚ | ⊚ | ◯ | ◯ | ⊚ | ⊚ |
| Example 32 | ◯ | ◯ | ⊚ | ⊚ | ◯ | ◯ | ⊚ | ⊚ |
| Comparative | X | X | X | X | X | X | Δ | X |
| Example 1 | | | | | | | | |
| Comparative | X | X | X | X | X | X | X | X |
| Example 2 | | | | | | | | |
| Comparative | X | Δ | X | X | X | Δ | X | X |
| Example 3 | | | | | | | | |
| Comparative | X | X | X | X | X | X | X | X |
| Example 4 | | | | | | | | |
| Comparative | Δ | Δ | X | X | Δ | X | X | X |
| Example 5 | | | | | | | | |
| Comparative | Δ | Δ | X | Δ | X | Δ | X | X |
| Example 6 | | | | | | | | |
| Comparative | Δ | Δ | Δ | Δ | Δ | Δ | X | Δ |
| Example 7 | | | | | | | | |
| Comparative | ◯ | Δ | X | X | Δ | Δ | Δ | X |
| Example 8 | | | | | | | | |
| Comparative | Δ | Δ | X | X | Δ | Δ | X | Δ |
| Example 9 | | | | | | | | |
| Comparative | ◯ | Δ | Δ | Δ | Δ | Δ | Δ | Δ |
| Example 10 | | | | | | | | |
| Comparative | ◯ | ◯ | Δ | Δ | X | Δ | Δ | Δ |
| Example 11 | | | | | | | | |

TABLE 5

| | PR 3 | | | | SOH | |
|---|---|---|---|---|---|---|
| | | Hump | | | | Hump |
| | EBR | height | RRC | Uniformity | EBR | height |
| Example 1 | Δ | ◯ | ◯ | ◯ | Δ | ◯ |
| Example 2 | ⊚ | ◯ | ◯ | ◯ | ◯ | ◯ |
| Example 3 | ⊚ | ⊚ | ◯ | ◯ | ◯ | ◯ |
| Example 4 | ◯ | ◯ | ◯ | ◯ | ◯ | ◯ |
| Example 5 | ⊚ | ⊚ | ◯ | ◯ | ◯ | ◯ |
| Example 6 | ⊚ | ⊚ | ◯ | ◯ | ◯ | ◯ |
| Example 7 | ⊚ | ⊚ | ◯ | ◯ | ◯ | ◯ |
| Example 8 | ⊚ | ⊚ | ◯ | ◯ | ◯ | ◯ |
| Example 9 | ⊚ | ⊚ | ◯ | ◯ | ◯ | ◯ |
| Example 10 | Δ | Δ | Δ | Δ | Δ | Δ |
| Example 11 | ◯ | ◯ | ◯ | Δ | ◯ | ◯ |
| Example 12 | ⊚ | ⊚ | ⊚ | ⊚ | ⊚ | ⊚ |
| Example 13 | ⊚ | ⊚ | ⊚ | ⊚ | ⊚ | ⊚ |
| Example 14 | ⊚ | ⊚ | ⊚ | ⊚ | ⊚ | ⊚ |
| Example 15 | ◯ | ◯ | ◯ | ◯ | ◯ | ◯ |
| Example 16 | Δ | Δ | Δ | ◯ | ◯ | ◯ |
| Example 17 | Δ | ◯ | ◯ | ◯ | Δ | ◯ |
| Example 18 | ◯ | ◯ | ⊚ | ⊚ | ⊚ | ⊚ |
| Example 19 | ⊚ | ⊚ | ⊚ | ⊚ | ⊚ | ⊚ |
| Example 20 | ⊚ | ⊚ | ⊚ | ⊚ | ⊚ | ⊚ |
| Example 21 | ⊚ | ⊚ | ⊚ | ⊚ | ⊚ | ⊚ |
| Example 22 | ◯ | ◯ | ◯ | ◯ | ◯ | ◯ |
| Example 23 | Δ | ◯ | Δ | Δ | Δ | ◯ |
| Example 24 | ⊚ | ⊚ | ⊚ | ⊚ | ⊚ | ◯ |
| Example 25 | ⊚ | ⊚ | ⊚ | ⊚ | ⊚ | ◯ |
| Example 26 | ⊚ | ⊚ | ⊚ | ⊚ | ⊚ | ◯ |
| Example 27 | ⊚ | ⊚ | ⊚ | ⊚ | ⊚ | ◯ |
| Example 28 | ⊚ | ⊚ | ⊚ | ⊚ | ⊚ | ◯ |
| Example 29 | ◯ | ◯ | ⊚ | ◯ | ◯ | ◯ |
| Example 30 | ◯ | ◯ | ⊚ | ◯ | ◯ | ◯ |
| Example 31 | ◯ | ◯ | ⊚ | ⊚ | ◯ | ◯ |
| Example 32 | ◯ | ◯ | ⊚ | ⊚ | ◯ | ◯ |
| Comparative | X | X | X | X | X | X |
| Example 1 | | | | | | |
| Comparative | X | X | X | X | X | X |
| Example 2 | | | | | | |
| Comparative | X | Δ | X | X | X | X |
| Example 3 | | | | | | |
| Comparative | X | X | X | X | X | X |
| Example 4 | | | | | | |
| Comparative | Δ | Δ | X | X | X | X |
| Example 5 | | | | | | |
| Comparative | Δ | Δ | X | X | Δ | Δ |
| Example 6 | | | | | | |
| Comparative | Δ | Δ | X | Δ | Δ | Δ |
| Example 7 | | | | | | |
| Comparative | Δ | ◯ | Δ | X | Δ | Δ |
| Example 8 | | | | | | |
| Comparative | Δ | Δ | X | Δ | Δ | X |
| Example 9 | | | | | | |
| Comparative | Δ | ◯ | Δ | Δ | X | X |
| Example 10 | | | | | | |
| Comparative | Δ | Δ | ◯ | Δ | X | X |
| Example 11 | | | | | | |

As shown in Tables 4 to 5 above, the thinner compositions of Examples 1 to 32 according to the present invention, which comprise a lactone-based organic solvent, an aliphatic ether compound having a specific structure, and one or more of a ketone-based organic solvent or an ester-based organic solvent, were confirmed to exhibit excellent EBR characteristics for photoresist films and spin-on hard masks (SOHs) and to reduce the hump height. Furthermore, it was confirmed that the thinner compositions of Examples 1 to 32 exhibit excellent RRC characteristics for photoresist films and can improve the uniformity of the coating film.

In contrast, the thinner compositions of Comparative Examples 1 to 11, which do not contain any one of a lactone-based organic solvent, an aliphatic ether compound having a specific structure, and one or more of a ketone-based organic solvent or and ester-based organic solvent, were found to have difficulty in simultaneously securing EBR characteristics, RRC characteristics, performance in lowering hump height, and uniformity of the coating film.

Although particular embodiments of the present invention have been shown and described, it will be understood by those skilled in the art that it is not intended to limit the present invention to the preferred embodiments, and it will be obvious to those skilled in the art that various changes and modifications may be made without departing from the spirit and scope of the invention.

The scope of the present invention, therefore, is to be defined by the appended claims and equivalents thereof.

1. A thinner composition comprising:
a lactone-based organic solvent;
a compound of formula (1); and
one or more of a ketone-based organic solvent or an ester-based organic solvent: 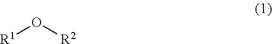
wherein,
R¹ and R² are each independently a C₂-C₈ hydrocarbon.

2. The thinner composition according to claim 1, wherein the lactone-based organic solvent is one or more selected from the group consisting of γ-butyrolactone, γ-valerolactone, δ-valerolactone, and ε-caprolactone.

3. The thinner composition according to claim 1, wherein R¹ and R² are each independently a C₂-C₈ alkyl.

4. The thinner composition according to claim 3, wherein the compound of formula (1) is one or more selected from the group consisting of diethyl ether, dipentyl ether, di-n-octyl ether, and ethylpropyl ether.

5. The thinner composition according to claim 1, wherein the ketone-based organic solvent is one or more selected from the group consisting of methyl ethyl ketone, cyclopentanone, and cyclohexanone.

6. The thinner composition according to claim 1, wherein the ester-based organic solvent is one or more selected from the group consisting of ethyl 3-ethoxypropionate, methyl 3-methoxypropionate, n-butyl acetate, methyl 2-hydroxyisobutyrate, and ethyl lactate.

7. The thinner composition according to claim 1, wherein the thinner composition comprises:
0.5 to 20 wt % of the lactone-based organic solvent;
0.0005 to 0.2 wt % of the compound of formula (1); and
79.8 to 99.3 wt % of one or more of the ketone-based organic solvent or the ester-based organic solvent.

8. The thinner composition according to claim 1, wherein the thinner composition comprises:
1 to 10 wt % of the lactone-based organic solvent;
0.001 to 0.1 wt % of the compound of formula (1); and
89.9 to 98.9 wt % of one or more of the ketone-based organic solvent or the ester-based organic solvent.

9. The thinner composition according to claim 1, wherein the thinner composition comprises:
0.5 to 20 wt % of the lactone-based organic solvent;
0.0005 to 0.2 wt % of the compound of formula (1);
30 to 60 wt % of the ketone-based organic solvent; and
35 to 65 wt % of the ester-based organic solvent.

10. The thinner composition according to claim 1, wherein the thinner composition does not comprise a glycol ether-based organic solvent.

11. The thinner composition according to claim 1, wherein the thinner composition is for one or more of a photoresist film or a spin-on hardmask (SOH).

12. The thinner composition according to claim 11, wherein the photoresist film is a photoresist film for ArF, KrF, or EUV.

13. A method of treating a substrate comprising:
modifying the substrate with the thinner composition according to claim 1, and
applying a photoresist or spin-on hard mask (SOH) on the modified substrate.

14. The method of claim 13, further treating the substrate with the thinner composition after applying the photoresist or spin-on hard mask (SOH) on the modified substrate.

15. A method of treating a substrate comprising:
applying a photoresist or spin-on hard mask (SOH) on the substrate to form a film, and
treating the film with the thinner composition according to claim 1.
